(19) United States
(12) Patent Application Publication
(10) Pub. No.: US 2021/0056508 A1
(43) Pub. Date: Feb. 25, 2021

(54) SYSTEM AND METHOD FOR AUTOMATICALLY CAPTURING TECHNOLOGY TRANSFER KNOWLEDGE

(71) Applicant: SIEMENS AKTIENGESELLSCHAFT, Muenchen (DE)

(72) Inventor: ARNAUD LASSALLE, SAINT ORENS DE GAMEVILLE (FR)

(21) Appl. No.: 16/997,108

(22) Filed: Aug. 19, 2020

(30) Foreign Application Priority Data
Aug. 19, 2019 (EP) 19192356

(51) Int. Cl. G06Q 10/10; G06Q 50/04; G06Q 10/06; G06Q 30/02; G06F 30/10; H04N 5/76; H04L 12/58

(52) U.S. Cl. CPC G06Q 10/101; G06Q 50/04; G06Q 10/067; H04L 51/02; G06F 30/10; H04N 5/76; G06Q 30/0201

(57) ABSTRACT

A method for automatically capturing technology transfer knowledge for the production of a new product includes acquiring a production process model being a predefined structured model enabling a listing of successive process steps required for producing the new product. automatically capturing missing information within the production process model, and outputting a completed production process model once all fields have been reviewed by the processing unit. A system for automatically capturing technology transfer knowledge for the production of a new product is also provided.

### CROSS-REFERENCE TO RELATED APPLICATION

This application claims the priority, under 35 U.S.C. § 119, of European Patent Application EP 19192356, filed Aug. 19, 2019; the prior application is herewith incorporated by reference in its entirety.

### BACKGROUND OF THE INVENTION

### Field of the Invention

The present invention relates to the transfer of technology from a first site at which a product is developed to another site at which the product that has been developed is going to be manufactured.

Pharmaceutical R&D aims to develop new products or molecules that can be then used at an industrial level. Typically, at some point of its development, a new product will be authorized to access the market, which requires an industrialization of its manufacturing. That overall process is known as New Product Introduction (NPI). It implies that product and process specifications that have been developed within a laboratory will be transferred from the R&D lab into the production factory. Such a transfer is called a technology transfer (or more commonly a “tech transfer”). Actually, R&D and Production teams are used to working in silos, and collaboration between them is limited so that they tend to interact only during the tech transfer.

A tech transfer is a process (or even a project) which includes:
physically transferring, from an issuing site (i.e. R&D lab) into a receiving site (i.e. industrial site) a new product, its manufacturing process, and a related analytical method (i.e. a precise method by which a process/product parameter or quality attribute is measured, typically in a Quality Control laboratory);
potentially scaling-up batch sizes while doing the transfer;
ensuring that the receiving site correctly masters the manufacturing process within its environment.

A problem may result from the fact that the issuing site is usually concerned with requirements of developing new products as fast as possible (time driven development), while the receiving site is usually concerned with production requirements closely linked to costs (cost driven production) which gives rise to two different approaches about the required information regarding a tech transfer.

There are actually two kinds of knowledge that need to be shared between people of the issuing site and of the receiving site:
explicit knowledge, which is formal and explicit, and can be easily communicated (i.e. product specifications);
tacit knowledge, which is highly personal, hard to formalize and therefore, difficult to communicate to others. It has an important cognitive dimension.

All along a tech transfer project, the issuing site has to provide the receiving site with a documentation explaining how to develop the concerned new product. That is a very burdensome task: for instance, a process step including 3 days of manipulation in a lab typically represents a documentation writing effort of 3 months, including meetings and discussions. On top of that, it happens also that the resulting documentation may lack some relevant information for the receiving site.

For instance, it is particularly problematic to capture tacit knowledge from R&D experts which might be required for the industrial production of a new product. That might then impact the transfer project duration time, and consequently, the time to market, and the costs related to a specific project.

### BRIEF SUMMARY OF THE INVENTION

It is accordingly an object of the invention to provide a system and a method for automatically capturing technology transfer knowledge, which overcome the hereinafore-mentioned disadvantages of the heretofore-known systems and methods of this general type, which improve the transfer of technology between an issuing site and a receiving site, and in which the system and the method are able to efficiently capture tacit knowledge and transform it into explicit knowledge, so that information about a new product or process can be easily transferred to a receiving site, sparing the need for creating huge documentation for a new process or product, as well as time and costs for producing a new product.

With the foregoing and other objects in view there is provided, in accordance with the invention, a method for automatically capturing technology transfer knowledge for the production of a new product, the method comprising:
acquiring a production process model, wherein the production process model is a predefined structured model enabling a listing of successive process steps required for producing the new product, and for each step, the predefined structured model includes one or several predefined fields that are each configured for enabling a recording of specific information (i.e. relevant technology transfer knowledge with respect to the concerned step) with respect to the production process of the new product;
automatically capturing missing information within the production process model, wherein a processing unit is configured for determining whether one or several of the predefined fields are free of the specific information, and for each of the predefined fields which is free of the specific information, then configuring the processing unit for:
i) automatically triggering and conducting a chatbot for collecting audio and/or textual information from a person involved in a development of the new product, and storing the collected audio and/or textual information as specific information for the concerned field; and/or
ii) automatically launching a video recording process for each field which is identified as requiring an equipment/machine handling for a process step of the production process, wherein the video recording process includes automatically detecting an interaction with the equipment/machine, starting a video recording of the handling of the equipment/machine, automatically stopping the recording, notably as soon as the processing unit determines that the interaction with the equipment/machine has stopped for a predetermined time threshold, and storing the video recording as specific information for the concerned field;
until all fields of the predefined structured model have been reviewed by the processing unit; and
outputting a completed production process model once all fields have been reviewed by the processing unit.

With the objects of the invention in view, there is also provided a system for automatically capturing technology transfer knowledge for the production of a new product, the system comprising:
an information acquisition system, connected to the processing unit and including at least an input device, e.g. a camera system and/or a keyboard device and/or a mouse device and/or a touchscreen device, for collecting information concerning production steps, the information acquisition system being further configured for acquiring a production process model that is a predefined structured model enabling a listing of successive process steps required for producing the new product, wherein for each step, the predefined structured model includes one or several predefined fields that are each configured for enabling a recording of specific information with respect to the production process of the new product;
a memory, connected to the information acquisition system, for storing the production process model and the specific information;
the processing unit, including one or several processors, the processing unit being connected to the memory and the information acquisition system, the processing unit being configured for automatically capturing, by controlling the information acquisition system, missing information within the production process model by determining whether one or several of the predefined fields are free of the specific information, and for each of the predefined fields which is free of the specific information, then the processing unit is configured for:
i) automatically triggering and conducting, by using the information acquisition system, a chatbot for collecting audio and/or textual information from a person involved in a development of the new product, and storing the collected audio and/or textual information as specific information for the concerned field; and/or
ii) automatically launching, by using the information acquisition system, a video recording process for each field which is identified as requiring an equipment/machine handling for a process step of the production process, wherein the video recording process includes automatically detecting an interaction with the equipment/machine, starting a video recording of the handling of the equipment/machine, automatically stopping the recording, notably as soon as the processing unit determines that the interaction with the equipment/machine has stopped for a predetermined time threshold, and storing the video recording in the memory as specific information for the concerned field;
until all fields of the predefined structured model have been reviewed by the processing unit; and
the processing unit being further configured for storing a completed production process model in the memory once all fields have been reviewed by the processing unit.

Advantageously, the present invention proposes a method and a system capable of automatically capturing, within an issuing site, information required for the production of a new product by following a production process model that serves as a guide for determining which information is required/missing and triggering specific actions for collecting the required/missing information.

Other features which are considered as characteristic for the invention are set forth in the appended claims.

Although the invention is illustrated and described herein as embodied in a system and a method for automatically capturing technology transfer knowledge, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a block diagram of a flowchart representing a method according to the invention;

FIG. 2 is a flowchart showing an example of a production process model for a new pharmaceutical process according to the invention; and

FIG. 3 is a diagrammatic, perspective view of a preferred embodiment of a system according to the invention.

### DETAILED DESCRIPTION OF THE INVENTION

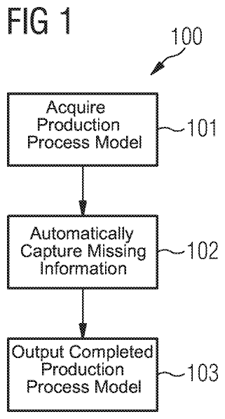

Referring now to the figures of the drawings in detail and first, particularly, to FIG. 1 thereof, there is seen an example of a method for automatically capturing technology transfer knowledge for the production of a new product. The method enables the automatic acquisition of knowledge with respect to the production of a new product, with the acquired knowledge being then easily transferable to a receiving site wherein industrial manufacturing of the new product will take place.

At step 101, the system according to the invention acquires a production process model. The production process model is based on a predefined structured model that enables the listing of successive process steps that are required for producing the new product. Preferentially, a database or memory of the system according to the invention may include several predefined structured models which have been developed each for a specific kind of production process, e.g. for the production of a drug, of a physical material, etc., wherein the predefined structured model might be classified according to technologies in the database. The predefined structured model is configured for structuring the product/process knowledge to be passed during a tech transfer, thanks to a knowledge model organized into assets. The system according to the invention is indeed capable of determining whether a knowledge asset is failing or not within the production process model.

Typically, the predefined structured model includes, for each step of the production process that is defined by the predefined structure model, one or several predefined fields that are each configured for enabling a recording of specific information or knowledge with respect to the production process of the new product. An operator of an issuing site may therefore choose/select in the database or memory one of the predefined structured models in function of the type of process or product to be developed, and that will have to be transferred to a receiving site. Optionally, the operator may fill one or some of the fields included within the selected predefined structured model. As soon as a predefined structured model has been selected by the operator, the system according to the invention is configured for acquiring that predefined structured model, i.e. it will upload it, e.g. into its memory, as a production process model that needs to be completed. The production process model acquired by the system according to the invention is thus one of the predefined structured models stored in a database, that has been selected by an operator, and that needs to be automatically completed by additional knowledge in order to describe the production process of a new product.

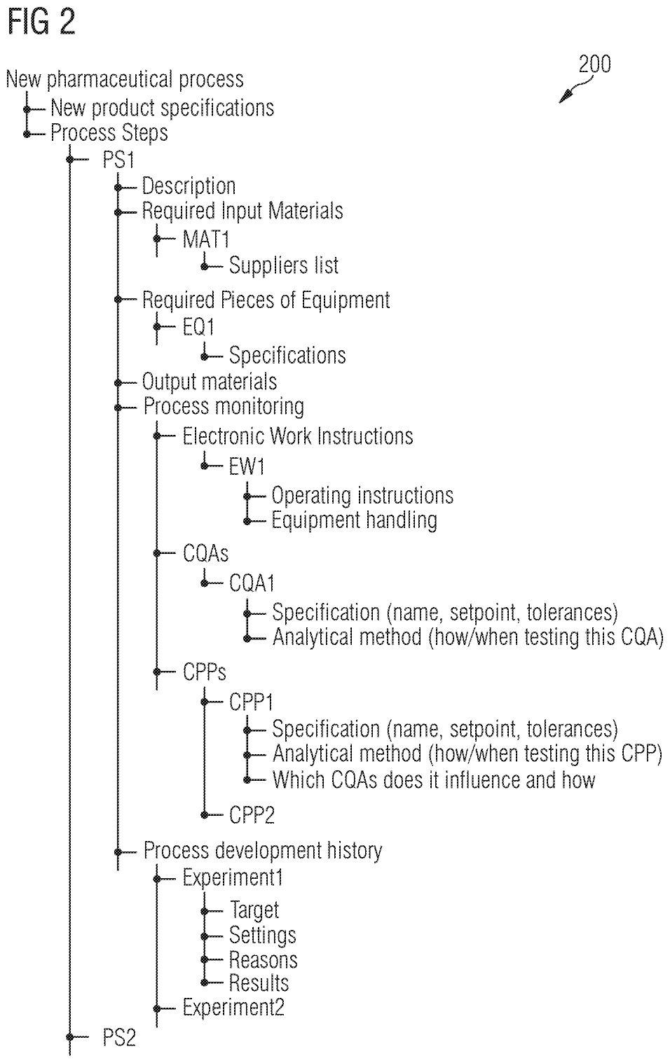

FIG. 2 shows a preferred example of a production process model 200, which is configured for structuring in a list of different process steps the knowledge related to a production process, e.g. a new pharmaceutical process, for a product.

For each process step, one or several fields are defined. The fields are for instance at least one or preferentially all of the following:
a description field, wherein the step has to be textually described and/or illustrated, e.g. by some pictures, and wherein a name or reference or identifier of the process step might be recorded;
a Bill Of Materials field, i.e. a list of input materials required to perform the step. For each input material, a list of suppliers can be also recorded;
a field for listing a set of machines or equipment which might be involved within the production process with respect to the considered step. For each equipment/machine, some information might be recorded like the category of equipment/machine, its function, its specifications, etc.;
optionally, a material field for providing a description of materials produced by the step;
an instruction field configured for specifying how the step has to be conducted, with the instruction field being configured for including one or all of the following features:
a) Electronic work instructions, including notably work instructions to be presented to an operator in charge of executing the step, as well as optionally know-how information configured for specifying equipment/machine handling with respect to the step;
b) a list of Critical Quality Attributes (CQAs) that are required for certifying a quality of the product with respect to the considered step, with the list being configured for enabling a specification of at least one value (e.g. setpoint, limit) for each CQAs and optionally a description of an analytical method to be performed in order to check each CQA;
c) a list of Critical Control Parameters (CPPs) to be monitored during the step, with the list being configured for enabling a specification of at least one value for each CPP (e.g. setpoint, limit) and optionally a description of an analytical method to be performed in order to check each CPP and an explanation of how each CPP influences one or several CQAs;
a history field configured for collecting information with respect to a history of experiments conducted during the development of the considered step. Preferentially, the history field is configured for recording within the production process model and for each step, its target, settings that have been made (e.g. on the pieces of equipment/machines), a special target of the experiment, measured results, etc.

As previously explained, the present invention proposes to create/generate such predefined structured models for different fields of technologies/products/production processes, wherein a selection of one of the predefined structured models triggers its acquisition/uploading by the system according to the invention, and then its completion through the automatic capture of missing information. The invention proposes to digitally record a completed production process model for each new product process. For this purpose and preferentially, the information acquisition system according to the invention may also include a collaborative graphical user interface for acquiring a knowledge from an operator of an issuing site.

At step 102, the system is configured for automatically capturing missing information within the production process model, wherein the processing unit is configured for determining whether one or several of the predefined fields are missing a specific information, and for each of the predefined fields which are missing some specific information, then the processing unit is configured for automatically conducting a chatbot and/or acquiring a video.

Preferentially, the chatbot is configured for interacting by voice with an operator. For instance, when the system according to the invention determines that a specific information, i.e. some knowledge asset requiring some verbal explanation, is missing and/or has not been explicitly defined yet, then the system is configured for automatically asking a predefined corresponding specific question to the operator and for automatically recording his or her response either in natural language and/or by using the collaborative graphical user interface.

The chatbot is therefore configured for collecting audio and/or textual information from the operator, and the system then automatically stores the collected audio and/or textual information as specific information for the concerned field. Typically, the chatbot will focus only on questions requiring some verbal explanation (such as an experiment observation, or a reason behind a key decision). Preferentially, the information acquisition system according to the invention includes as an input device a headphone/microphone combo for recording each answer to chatbot questions in natural language. Preferentially, each answer is recorded by the system in 2 formats: as an audio file and as a textual information after having been parsed by a voice recognition algorithm. Optionally, the system according to the invention is configured for enabling an operator amending a displayed textual information directly in the collaborative graphical user interface.

In the following, some examples of questions that can be asked by the chatbot according to the invention are presented:
In the case of a process step called “formulation,” wherein the system detects that there are no recorded operating instructions, then the chatbot is configured for providing the following message: “Do you want to describe some working instructions for process step called ‘formulation’?”. If the operator answers “yes” within an acceptable response time predefined within the system, then the latter is configured for automatically recording an explanation of the operator and storing the explanation as a textual information as an EWI of the instruction field;
If, for a given CPP, there is no “Impact on CQA” recorded, the chatbot will ask: “Do you know which are the CQAs influenced by the ‘reactor speed’ CPP?”
If, for a given experiment, there is no input reason, the chatbot will ask: “What was the purpose of the experiment ‘248’?”
If, for a given experiment, there is no input result, the chatbot will ask: “What was the observation you made from experiment ‘248’?”
Etc.

Consequently, the system according to the invention is capable of translating tacit knowledge into textual information. Advantageously, the resulting textual information might then be used for some advanced searching actions on previous input information, from past experiments or product developments, and/or for automatically translating the initial language of the voice recording into another language, and/or for making correlations between past experiments observations.

Preferentially, the chatbot is automatically launched by the system according to the invention as soon as the system identifies an operator involved in the production process of the new product, e.g. from a logging of the operator into the system according to the invention of the operator or into a network connected to the system according to the invention. Preferentially, the system might be configured for sending an email to the operator, wherein the email includes a question of the chatbot in the case that the question has not yet been responded to by the operator if a predefined time period has lapsed since the last time the question was asked or since the last time the operator was identified. In this case, the system is further configured for collecting an email response from the operator with respect to the sent question and to record the response as a textual information into a corresponding field of the production process model. In particular, if the operator does not answer to the email after a predefined time period, then the system is configured for sending the previously sent email to a peer of the operator who is also part of the same tech transfer project. For this purpose, the system may include in its database a list of persons involved for each tech transfer project.

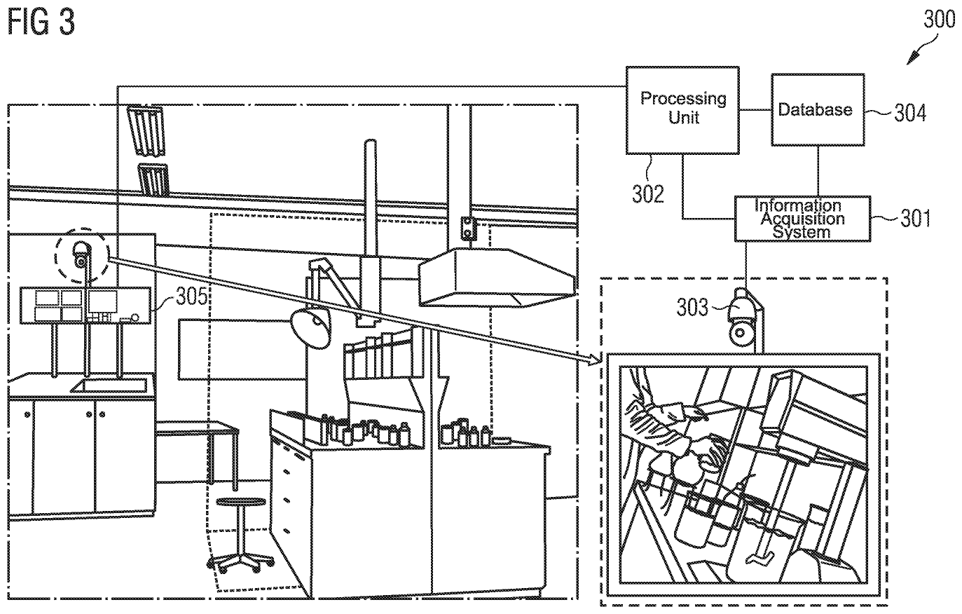

FIG. 3 shows a preferred embodiment of the system 300 according to the invention. It includes an information acquisition system 301 connected to a processing unit 302 including one or several processors, and including at least one input device configured for acquiring information regarding the production process. Such an input device is for instance a video camera system 303. It might be also a microphone, a keyboard, a touchscreen, or any device which enables the acquisition of information by observing a scene representing a step of the production process and/or by interacting with an operator. The system 300 may further include a memory or database 304 for storing any record, as well as the predefined structured models. The database 304 is for instance connected to the processing unit 302 and/or the information acquisition system 301. Optionally, the system 300 may also include one or several displays 305 and/or a collaborative graphical user interface. The information acquisition system 301 is typically configured for being installed within a laboratory in order to acquire production process knowledge from development steps of the production process for a new product.

Instead of the chatbot or together or in cooperation with the chatbot, the processing unit 302 is configured for controlling the camera system 303 for acquiring missing information with respect to one or several fields of the production process model. For instance, it is configured for detecting a handling or use of a specific machine or equipment within the laboratory, with the detection triggering the start of a video recording process. The video recording process may automatically start a recording of a process step of the production process by using the camera as soon as an interaction of an operator with the machine or equipment is detected or identified, and/or may use the chatbot for asking the operator whether the handling has to be recorded and only starts the recording in the case of an identification of a positive answer from the operator. The video recording enables a collection of additional know-how with respect to machine/equipment handling for a considered step of the production process.

Preferentially, the processing unit is configured for identifying within images of a laboratory, each equipment/machine that might be potentially used with respect to a production process. From this knowledge of the position and/or from a connection to some equipment/machine, the system according to the invention is able to identify whether an operator is going to interact or is interacting with the equipment machine. The identification might be based for instance on a machine learning algorithm configured for detecting an interaction of an operator with a machine/equipment from a flow of images acquired by the video system. For instance, if an interaction is detected in images acquired by the camera system 303, then the processing unit 302 may automatically start a video recording of the handling of the equipment/machine until an end of the interaction with the machine/equipment is detected, at which time the processing system 302 automatically stops the recording and stores a corresponding video file in the memory 304 for a specific field of the production process model. The field is for instance a field including an indication that the machine/equipment has to be used for the corresponding step. For instance, the processing unit is configured for identifying each field of the production process model including a handling of the machine/equipment, and asking through the chatbot which of the fields is the correct one with respect to the concerned step. Preferentially, the information acquisition system may also include a motion sensor that may cooperate with the camera system 303 in order to trigger the start of the recording. The motion sensor is typically configured for detecting motion with respect to a single machine/equipment within the laboratory. In that case, the processing unit 302 will start the video recording process each time the motion sensor made a detection for the single machine/equipment, by activating a camera of the camera system which points to the single machine/equipment, or which includes the single machine/equipment in its field of view. Preferentially, at the end of the video recording session, a message is sent to the laboratory operator, e.g. through the chatbot, or through a loudspeaker of the information acquisition system, asking the operator whether he or she wants to keep or erase the video record. Preferably, if the operator selects to keep the video record, then the chatbot might be configured for asking the operator to input some contextual information on that record. A microphone or any other input device of the information acquisition system 301 might be used for recording the contextual information provided by the operator. Preferentially, the contextual information provided by the operator is automatically recorded in two formats: as an audio file and as a textual information after having been parsed by a voice recognition algorithm. Optionally, the system is configured for enabling the operator amending a displayed textual information directly in the collaborative graphical user interface.

The contextual information could typically contain a process step name, reference, or identifier, as well as a description of the step or some observations made by the lab operator, etc. The video record, along with the recorded contextual information, might be then automatically and jointly stored in the memory 304 (at the right location with respect to the field, thanks to the added context), allowing the system to link it to the correct production process field. Eventually, information recorded with respect to the handling of a machine/equipment might be automatically integrated into some electronic work instruction for the considered production process step, and might then be automatically displayed by the system to a shop floor operator asked to do the same kinds of equipment/machine handling on a production line.

The processing unit 302 is thus configured for checking whether each field of the production process model has been reviewed. By reviewing, it has to be understood that for each field, the system will automatically record some information or withdraw the field from the production process step due to an acquisition of information by the system and from the operator that the field is not relevant or required with respect to the production process step.

Once all fields have been reviewed by the processing unit 302, the system automatically outputs, at step 103, a completed production process model that can be used by a receiving site for the industrial production of a product according to the production process steps developed by the issuing site.

As compared to existing solutions, the present invention presents the following advantages:
it accelerates the pharmaceutical time-to-market, by automatizing a human knowledge transfer process in a very usable and flexible way, making this knowledge reusable for future development projects within R&D and during tech transfers towards production, reducing development costs, and improving tech transfer First-Time Right Ratio (i.e. the ratio of getting things right the first time, to better manage risk assessment, which means doing more defect prevention than defect detection and reworking).
it is able to extract tacit knowledge from an interaction with an operator or by recording actions/experiments realized in a lab, so that a corresponding knowledge is automatically made available within a predefined structured production process model.

Other advantages of the present invention are also:
a deeper understanding of the product and process;
a reduction in time and effort for a tech transfer project;
a paper documentation reduction;
a First Time Right improvement;
a deeper collaboration between R&D and Production stakeholders;
a continuous improvement with the Closed-Loop Manufacturing approach;
a correlation between laboratory batches/experiments and production batches;
a reduction in time and effort of future product development projects.

1. A method for automatically capturing technology transfer knowledge for a production of a new product, the method comprising:
a) acquiring a production process model, the production process model being a predefined structured model enabling a listing of successive production process steps required for producing the new product;
b) automatically capturing missing information within the production process model; and
c) outputting a completed production process model once all fields have been reviewed by a processing unit.

2. The method according to claim 1, wherein for each step of the production process, the predefined structured model includes one or several predefined fields each being configured for enabling an automatic recording of specific information with respect to the production process of the new product.

3. The method according to claim 2, which further comprises using the processing unit for determining whether one or several of the predefined fields are free of the specific information.

4. The method according to claim 3, which further comprises for each of the predefined fields being free of the specific information, subsequently using the processing unit for at least one of:
automatically triggering and conducting a chatbot, or
automatically launching a video recording process for each field being identified as requiring an equipment/machine handling for a process step of the production process
until all fields of the predefined structured model have been reviewed by the processing unit.

5. The method according to claim 4, which further comprises using the processing unit for collecting at least one of audio or textual information by using the chatbot and with respect to a process step for producing the new product, and storing the collected at least one of audio or textual information as specific information for a concerned field.

6. The method according to claim 5, which further comprises using the video recording process to automatically detect an interaction with the equipment/machine, starting a video recording of a handling of the equipment/machine, automatically stopping the recording, and storing a video recording as the specific information for the concerned field.

7. A system for automatically capturing technology transfer knowledge for a production of a new product, the system comprising:
a processing unit;
an information acquisition system connected to said processing unit, said information acquisition system including at least an input device for automatically collecting information concerning a production step, said information acquisition system configured for acquiring a production process model being a predefined structured model enabling a listing of successive process steps required for producing the new product, for each step, the predefined structured model including one or several predefined fields each being configured for enabling a recording of specific information with respect to the production process of the new product; and
a memory connected to said information acquisition system for storing the production process model and the specific information;
said processing unit being configured for automatically capturing, by controlling said information acquisition system, missing information within the production process model until all fields of the predefined structured model have been reviewed by said processing unit, and said processing unit being further configured for automatically storing a completed production process model in said memory once all fields have been reviewed by said processing unit.

8. The system according to claim 7, wherein for each of the predefined fields being free of the specific information, the processing unit is configured for at least one of:
i) automatically triggering and conducting, by using said information acquisition system, a chatbot for collecting at least one of audio or textual information from a person involved in a development of the new product, and storing the at least one of collected audio or textual information as specific information for the concerned field, or
ii) automatically launching, by using said information acquisition system, a video recording process for each field being identified as requiring an equipment/machine handling for a process step of the production process.

9. The system according to claim 8, wherein the video recording process includes automatically detecting an interaction with the equipment/machine, starting a video recording of the handling of the equipment/machine upon a detected interaction, automatically stopping the recording upon an end of the detected interaction, and storing the video recording in said memory as the specific information for the concerned field.

10. The system according to claim 7, wherein said information acquisition system includes a camera system.

11. The system according to claim 7, wherein said information acquisition system includes a motion sensor.
